(19) United States
(12) Patent Application Publication
(10) Pub. No.: US 2015/0137138 A1
(43) Pub. Date: May 21, 2015

(54) TRANSISTOR AND METHOD FOR PRODUCING TRANSISTOR

(71) Applicant: MURATA MANUFACTURING CO., LTD., Kyoto-fu (JP)

(72) Inventors: Kiyoto ARAKI, Kyoto-fu (JP); Shotaro HASHIMOTO, Kyoto-fu (JP); Masakazu TAKAO, Kyoto-fu (JP)

(73) Assignee: MURATA MANUFACTURING CO., LTD., Kyoto-fu (JP)

(21) Appl. No.: 14/573,188

(22) Filed: Dec. 17, 2014

Related U.S. Application Data
(63) Continuation of application No. PCT/JP2013/067319, filed on Jun. 25, 2013.

(30) Foreign Application Priority Data
Jul. 13, 2012 (JP) 2012-157583

(51) Int. Cl. H01L 29/51; H01L 29/66; H01L 21/8234; H01L 21/02; H01L 27/088; H01L 29/78; H01L 29/40

(52) U.S. Cl. CPC H01L 29/517; H01L 29/78; H01L 29/66477; H01L 29/408; H01L 21/02274; H01L 27/088; H01L 21/823462
USPC 257/76; 438/275

(57) ABSTRACT

A transistor that offers a high dielectric breakdown voltage of a gate insulating film with limited reduction of the current flowing between drain and source electrodes. The transistor has a semiconductor layer, a gate insulating film on the semiconductor layer, a gate electrode on the gate insulating film, and a source electrode and a drain electrode disposed on the semiconductor layer with the gate electrode therebetween. The concentration of the impurities contained in the gate insulating film is on a downward gradient starting at the surface of the gate insulating film on the semiconductor layer side and ending at the surface of the gate insulating film on the gate electrode side.

### CROSS REFERENCE TO RELATED APPLICATIONS

This application claims benefit of priority to Japanese Patent Application No. 2012-157583 filed Jul. 13, 2012, and to International Patent Application No. PCT/JP2013/067319 filed Jun. 25, 2013, the entire content of each of which is incorporated herein by reference.

### TECHNICAL FIELD

The present technical field relates to a transistor having a gate insulating film and a method for producing a transistor.

### BACKGROUND

Transistors, such as those disclosed in Japanese Unexamined Patent Application Publication No. 2010-98141, have hitherto been used as signal amplifiers in electronic circuits.

FIG. 4 illustrates an example of a known transistor. FIG. 4 is a cross-sectional view of a known transistor 200.

The transistor 200 illustrated in FIG. 4 has a semiconductor layer 102 consisting of a GaN layer 102a and an AlGaN layer 102b on a substrate 101.

A source electrode 105 and a drain electrode 106 are disposed on the semiconductor layer 102.

A connection electrode 112 is disposed on the source electrode 105 and the drain electrode 106.

A gate insulating film 107 is disposed on a portion of the semiconductor layer 102.

A gate electrode 108 is disposed on a portion of the gate insulating film 107.

A protective film 109 is disposed on a portion of the gate insulating film 107.

Surface-protecting resin 115 made of polyimide resin or any similar material is disposed on the gate electrode 108, the protective film 109, and the connection electrode 112.

In this known transistor 200, the gate insulating film 107, made of aluminum oxide or any similar material, is usually formed using atomic layer deposition (ALD), a process that offers excellent height-gap coating, film-thickness uniformity, and film-thickness controllability.

The following describes an example of a method for forming the gate insulating film 107 using atomic layer deposition.

First, TMA (Tri Methyl Aluminum; chemical formula, Al (CH₃)₃) as a first reactant is supplied onto the semiconductor layer 102 to make TMA adsorbed to the surface of the semiconductor layer 102. The residual, unadsorbed TMA is then eliminated. Then O₃ as a second reactant is supplied onto the semiconductor layer 102 so as to react with the TMA adsorbed to the semiconductor layer 102. The residual, unreacted O₃ is then eliminated, so that a monatomic layer of aluminum oxide is formed. This series of cycles is repeated to form the desired gate insulating film 107, which consists of multiple atomic layers of aluminum oxide.

The low reactivity of O₃, however, led to insufficient reaction between O₃ and TMA in some cases, causing impurities such as H atoms and C atoms to remain in aluminum oxide. This caused a reduced density of the aluminum oxide film and an accordingly reduced dielectric breakdown voltage of the gate insulating film 107.

As a solution to this, there was a method in which O₂ plasma was supplied as the second reactant in the above atomic layer deposition process instead of O₃ to improve the dielectric breakdown voltage of the gate insulating film 107.

Furthermore, as a way to improve the dielectric breakdown voltage of the gate insulating film 107, there was a method in which O₃ was supplied as the second reactant in the above atomic layer deposition process, followed by irradiation with O₂ plasma on an as-needed basis, as described in Japanese Unexamined Patent Application Publication No. 2009-152640.

O₂ plasma is more reactive with TMA than O₃ is. The use of O₂ plasma therefore prevents impurities such as H atoms and C atoms from remaining in the aluminum oxide film and ensures a high density of the aluminum oxide film.

FIG. 5 illustrates an example of the dielectric breakdown voltage (MV/cm) of gate insulating films formed using this known method. (A) in FIG. 5 represents the dielectric breakdown voltage of a gate insulating film formed using O₃ as the second reactant. (B) in FIG. 5 represents the dielectric breakdown voltage of a gate insulating film formed using O₂ plasma as the second reactant. Both gate insulating films have a thickness of 30 nm. As can be seen from FIG. 5, the use of O₂ plasma as the second reactant in the atomic layer deposition process improved the dielectric breakdown voltage of the gate insulating film compared to the use of O₃.

### SUMMARY

### Technical Problem

However, forming the gate insulating film 107 using O₂ plasma mentioned above often causes the semiconductor layer 102 to be damaged because of the high reactivity of O₂ plasma. As a result, there was the problem of reduced concentration of electrons in the damaged semiconductor layer 102 resulting in reduced current flowing between the drain and source electrodes of the transistor 200.

An object of the present disclosure is to provide a transistor that offers a high dielectric breakdown voltage of a gate insulating film with limited reduction of the current flowing between drain and source electrodes and a method for producing such a transistor.

### Solution to Problem

To attain this object, a transistor according to the present disclosure has a semiconductor layer, a gate insulating film on the semiconductor layer, a gate electrode on the gate insulating film, and a source electrode and a drain electrode disposed on the semiconductor layer with the gate electrode therebetween. The concentration of an impurity contained in the gate insulating film is on a downward gradient starting at the surface of the gate insulating film on the semiconductor layer side and ending at the surface of the gate insulating film on the gate electrode side.

A method according to the present disclosure for producing a transistor includes providing a semiconductor layer, forming a first gate insulating film on the semiconductor layer through a first atomic layer deposition process using a first reactant and a second reactant, forming a second gate insulating film on the first gate insulating film through a second atomic layer deposition process using a first reactant and a second reactant, forming a gate electrode on the second gate insulating film, and forming a source electrode and a drain electrode on the semiconductor layer with the gate electrode therebetween. The second reactant used in the second atomic layer deposition process is more reactive than the second reactant used in the first atomic layer deposition process. The second gate insulating film contains an impurity at a lower concentration than the first gate insulating film does.

### Advantageous Effects of Disclosure

According to the present disclosure, a transistor can be obtained that offers a high dielectric breakdown voltage of a gate insulating film with limited reduction of the current flowing between drain and source electrodes.

### BRIEF DESCRIPTION OF THE DRAWINGS

FIGS. 1 (A) to 1(E) are cross-sectional diagrams illustrating respective steps applied in a method for producing a transistor 100 according to an embodiment of the present disclosure.

FIGS. 2 (F) to 2(I) are, continued from FIGS. 1(A) to 1(E), cross-sectional diagrams illustrating respective steps applied in a method for producing a transistor 100 according to an embodiment of the present disclosure. FIG. 2 (I) is also a cross-sectional view of a finished transistor 100.

FIG. 3 is a graph comparing the dielectric breakdown voltage of a gate insulating film formed using a method according to the present disclosure with that of a gate insulating film formed using a known method.

FIG. 4 is a cross-sectional view of a known transistor 200.

FIG. 5 is a graph illustrating the dielectric breakdown voltage of a gate insulating film formed using a known method.

### DETAILED DESCRIPTION

The following describes an illustrative embodiment of the present disclosure with drawings.

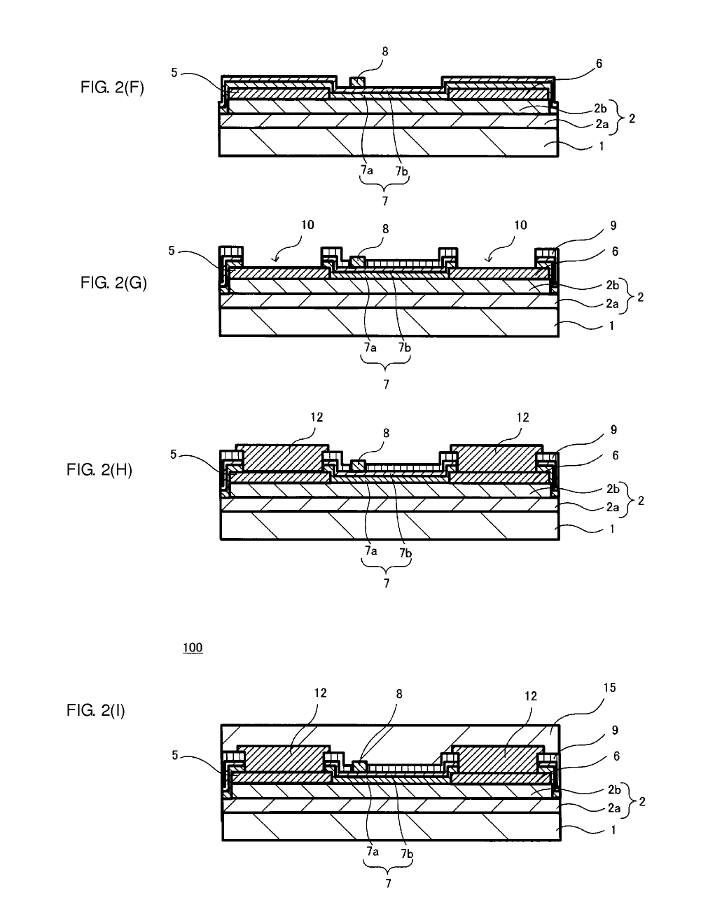

FIG. 2 (I) illustrates a cross-sectional view of a transistor 100 according to an embodiment of the present disclosure.

The transistor 100 has a semiconductor layer 2 consisting of a gallium nitride layer 2a and an aluminum gallium nitride layer 2b on a substrate 1 made of gallium nitride, silicon, silicon carbide, or any similar material.

A source electrode 5 and a drain electrode 6 both made of materials including titanium, aluminum, and so forth are disposed on the semiconductor layer 2.

A connection electrode 12 made of materials including gold and so forth is disposed on the source electrode 5 and the drain electrode 6.

A first gate insulating film 7a made of aluminum oxide or any similar material is disposed on a portion of the semiconductor layer 2. The first gate insulating film 7a contains either or both of hydrogen atoms and carbon atoms as impurities.

A second gate insulating film 7b made of aluminum oxide or any similar material is disposed on the first gate insulating film 7a. The second gate insulating film 7b contains either or both of hydrogen atoms and carbon atoms as impurities in common with the first gate insulating film 7a, but at a lower concentration than the first gate insulating film 7a does. Having this gate insulating film 7b with a low concentration of impurities in the gate insulating film 7, the transistor 100 offers a high dielectric breakdown voltage of the gate insulating film 7.

The first gate insulating film 7a is formed through an atomic layer deposition process in which TMA is used as a first reactant and ozone as a second reactant. The first gate insulating film 7a is formed using ozone, a material with low reactivity, in the atomic layer deposition process, therefore with little damage to the semiconductor layer 2 caused by the irradiation with the ozone.

The second gate insulating film 7b is, unlike the first gate insulating film 7a, formed through an atomic layer deposition process in which TMA is used as a first reactant and oxygen plasma as a second reactant. The second gate insulating film 7b is formed on the first gate insulating film 7a, which ensures that the damage to the semiconductor layer 2 caused by the irradiation with oxygen plasma is minor despite the high reactivity of oxygen plasma. The present disclosure therefore allows the first gate insulating film 7a and the second gate insulating film 7b to be formed causing limited damage to the semiconductor layer 2 and therefore a limited decrease in the concentration of electrons in the semiconductor layer 2. As a result, limited reduction of the current flowing between the drain and source electrodes due to decreased concentration of electrons is ensured.

Having this gate insulating film 7, the transistor 100 according to an embodiment of the present disclosure offers a high dielectric breakdown voltage of the gate insulating film 7 with limited reduction of the current flowing between the drain and source electrodes.

A gate electrode 8 made of materials including gold, nickel, and so forth is disposed on a portion of the second gate insulating film 7b.

A protective film 9 made of silicon nitride or any similar material is disposed on a portion of the second gate insulating film 7b.

Surface-protecting resin 15, such as polyimide resin, is disposed on the protective film 9 and the connection electrode 12.

The following describes an example of a method for producing a transistor 100 according to an embodiment of the present disclosure, the transistor having the structure described above.

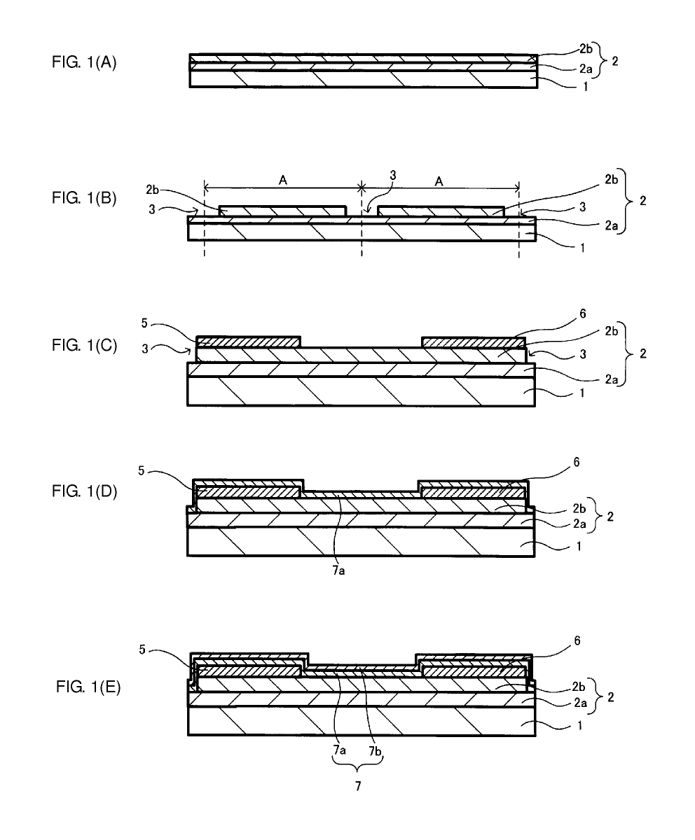

FIGS. 1 (A) to 2 (I) are each a cross-sectional diagram illustrating each step applied in a method for producing the transistor 100 according to this embodiment. FIGS. 1 (C) to 2 (I) are enlarged views of section A in FIG. 1 (B).

First, as illustrated in FIG. 1 (A), a gallium nitride layer 2a is formed using MOCVD (Metal Organic Chemical Vapor Deposition) on a substrate 1 made of gallium nitride, silicon, silicon carbide, or any similar material. Then an aluminum gallium nitride layer 2b is formed on the gallium nitride layer 2a using MOCVD to complete a semiconductor layer 2.

Then as illustrated in FIG. 1 (B), chamfers 3 having a desired depth are cut in a portion of the semiconductor layer 2 through dry etching or any similar process to electrically isolate each section A of the semiconductor layer 2.

If necessary, a portion of the semiconductor layer 2 is removed through photolithography and dry etching to form gate recesses (not illustrated) that give the transistor 100 functions such as serving as a normally-off transistor.

Then as illustrated in FIG. 1 (C), a source electrode 5 and a drain electrode 6 both made of materials including titanium, aluminum, and so forth are formed on the semiconductor layer 2 through photolithography and vacuum deposition. Then the surface of contact between each of the source electrode 5 and the drain electrode 6 and the semiconductor layer 2 may optionally be made into an ohmic contact through heat treatment.

Then as illustrated in FIG. 1 (D), a first gate insulating film 7a made of aluminum oxide is formed on the semiconductor layer 2, the source electrode 5, and the drain electrode 6 through a first atomic layer deposition process consisting of steps 1 to 4 below.

In step 1, TMA as a first reactant is supplied into the processing chamber in which the substrate 1 is stored. Through this, a monatomic layer of TMA is adsorbed to the semiconductor layer 2, the source electrode 5, and the drain electrode 6.

In step 2, the residual, unadsorbed TMA is eliminated from the processing chamber using a dry pump or any similar equipment. In addition to this, an inert gas such as a nitrogen gas is supplied into the processing chamber for a certain period of time.

In step 3, ozone is introduced into the processing chamber. The TMA adsorbed in step 1 and the ozone react with each other, forming a monatomic layer of aluminum oxide.

In step 4, ozone is eliminated from the processing chamber using a dry pump or any similar equipment. In addition to this, an inert gas such as a nitrogen gas is supplied into the processing chamber for a certain period of time.

Steps 1 to 4 are repeated a predetermined number of times to form a first gate insulating film 7a made of aluminum oxide with a predetermined thickness.

Then as illustrated in FIG. 1 (E), a second gate insulating film 7b made of aluminum oxide is formed on the first gate insulating film 7a through a second atomic layer deposition process consisting of steps 1 to 4 below.

In step 1, TMA as a first reactant is supplied into a processing chamber as in the first atomic layer deposition process described above. Through this, TMA is deposited on the first gate insulating film 7a.

In step 2, the residual, unadsorbed TMA is eliminated from the processing chamber using a dry pump or any similar equipment. In addition to this, an inert gas such as a nitrogen gas is supplied into the processing chamber for a certain period of time.

In step 3, an oxygen gas is introduced into the processing chamber, and then radio frequency power is applied between electrodes provided in the processing chamber to excite the oxygen gas into plasma. The oxygen gas excited into plasma (oxygen plasma) reacts with the TMA deposited on the first gate insulating film 7a.

In step 4, the oxygen gas is eliminated from the processing chamber using a dry pump or any similar equipment, and the radio frequency power applied between the electrodes is stopped. In addition to this, an inert gas such as a nitrogen gas is passed into the processing chamber for a certain period of time.

Steps 1 to 4 are repeated a predetermined number of times to form a second gate insulating film 7b with a predetermined thickness on the first gate insulating film 7a.

Because of the higher reactivity of oxygen plasma than that of ozone, the second gate insulating film 7b made of aluminum oxide contains impurities, which include hydrogen atoms and/or carbon atoms, at a lower concentration than the first gate insulating film 7a does. The concentration of the impurities contained in the first gate insulating film 7a and the second gate insulating film 7b of the transistor 100 is therefore on a downward gradient starting at the surface of the first gate insulating film 7a on the semiconductor layer 2 side and ending at the top surface of the second gate insulating film 7b, which is on the gate electrode 8 side. As a result, a second gate insulating film 7b with a low concentration of impurities is formed in the gate insulating film 7 as mentioned above, ensuring a high dielectric breakdown voltage of the gate insulating film 7 in the transistor 100.

In a production method according to this embodiment, in which the second gate insulating film 7b is formed using oxygen plasma after the formation of the first gate insulating film 7a, the oxygen plasma is blocked by the first gate insulating film 7a and thus is unlikely to reach the semiconductor layer 2. As a result, the semiconductor layer 2 is unlikely to be damaged by being irradiated with oxygen plasma.

Then as illustrated in FIG. 2 (F), a gate electrode 8 made of materials including gold, nickel, and so forth is formed on the second gate insulating film 7b through photolithography and vacuum deposition.

Then as illustrated in FIG. 2 (G), a protective film 9 made of silicon nitride or any similar material is formed between the source electrode 5 and the drain electrode 6 through CVD. Subsequently, the protective film 9 on the gate electrode 8 and the first gate insulating film 7a, the second gate insulating film 7b, and the protective film 9 on the source electrode 5 and the drain electrode 6 are removed through photolithography and dry etching to create openings 10, exposing a portion of the gate electrode 8, a portion of the source electrode 5 and a portion of the drain electrode 6.

Then as illustrated in FIG. 2 (H), connection electrodes 12 and 12 made of materials including gold, aluminum, and so forth are formed through photolithography and vacuum deposition to reduce the resistance of the source electrode 5 and the drain electrode 6.

Lastly, as illustrated in FIG. 2 (I), surface-protecting resin 15, such as polyimide resin, is formed on the protective film 9 and the connection electrodes 12, with a portion of the connection electrodes 12 and 12 exposed, to complete the transistor 100.

In this way, the present disclosure allows a layer with a low concentration of impurities to be formed in the gate insulating film 7 causing limited damage to the semiconductor layer 2 as a result of the gate insulating film 7 being formed by the first gate insulating film 7a and the second gate insulating film 7b. As a result, the dielectric breakdown voltage of the gate insulating film 7 is improved with limited reduction of the current flowing between the drain and source electrodes of the transistor 100.

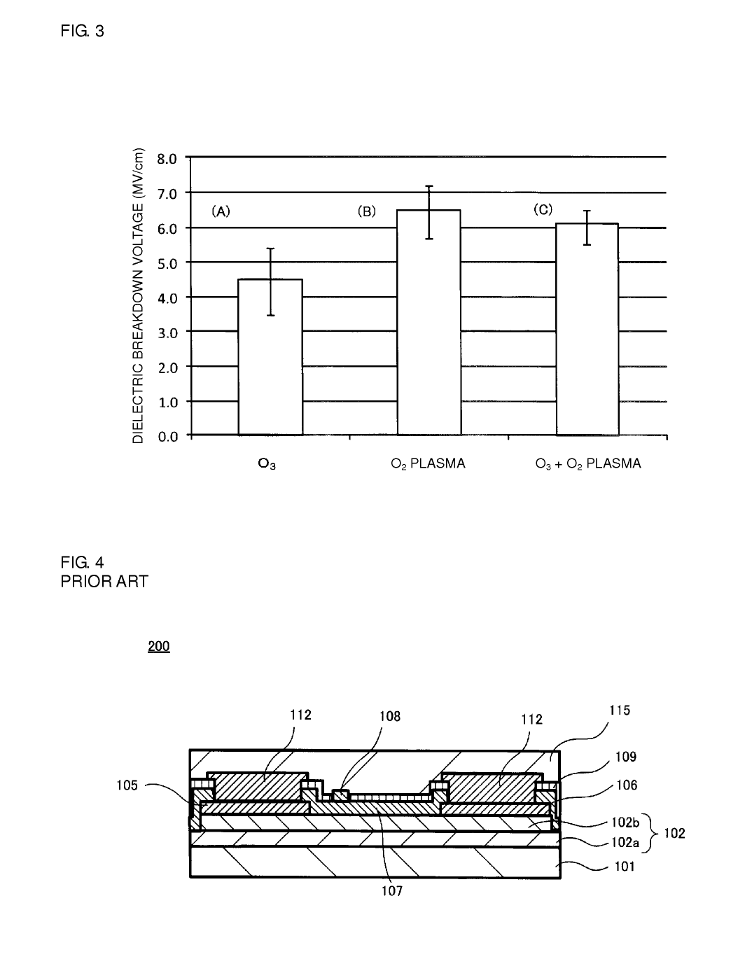

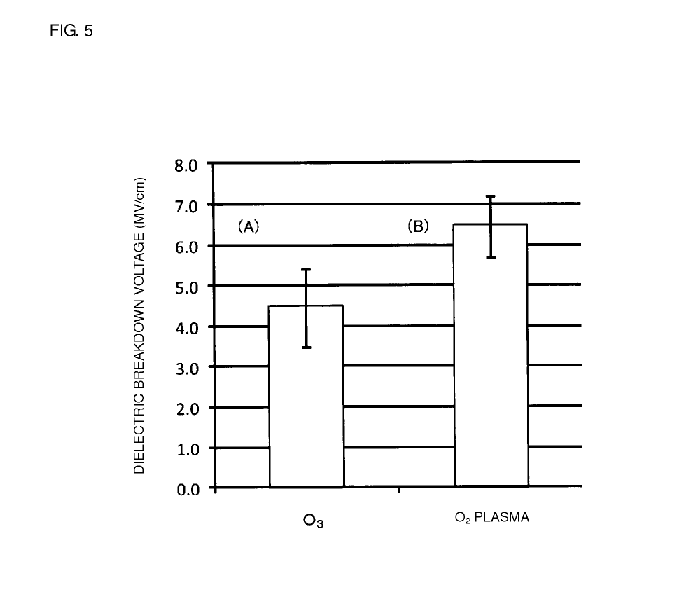

FIG. 3 is a graph comparing the dielectric breakdown voltage of a gate insulating film formed using a method according to the present disclosure with the dielectric breakdown voltage of a gate insulating film formed using a known method. (A) in FIG. 3 represents the dielectric breakdown voltage of a gate insulating film formed through a known atomic layer deposition process using TMA as a first reactant and ozone as a second reactant. (B) in FIG. 3 represents the dielectric breakdown voltage of a gate insulating film formed through a known atomic layer deposition process using TMA as a first reactant and oxygen plasma as a second reactant. (C) in FIG. 3 represents the dielectric breakdown voltage of a gate insulating film formed through the method described in this embodiment, the gate insulating film having a first gate insulating film and a second gate insulating film.

The gate insulating films in (A) to (C) in FIG. 3 have the same thickness, 30 nm. The first gate insulating film and the second gate insulating film in (C) in FIG. 3 have a thickness of 15 nm each.

As can be seen from FIG. 3, the dielectric breakdown voltage of the gate insulating film represented by (C) in FIG. 3 is higher than the dielectric breakdown voltage of the gate insulating film represented by (A) in FIG. 3 and, furthermore, compares favorably with the dielectric breakdown voltage of the gate insulating film represented by (B) in FIG. 3.

Transistors and methods for producing them according to the present disclosure are not limited to this embodiment. Various changes can be made within the gist of the disclosure.

For example, the semiconductor layer 2, which contains a gallium nitride layer 2a and an aluminum gallium nitride layer 2b in this embodiment, can be formed by a gallium arsenide layer and an aluminum gallium arsenide layer or the like. The second reactant used in the first atomic layer deposition process can be vapor or any similar material instead of ozone. The second reactant used in the second atomic layer deposition process can be plasma generated from carbon dioxide, vapor, or any similar material instead of oxygen plasma. The first gate insulating film 7a and the second gate insulating film 7b can be made of an oxide such as silicon oxide or hafnium oxide or an insulator material, e.g., a nitride such as silicon nitride or aluminum nitride, rather than aluminum oxide. The nitride material can be formed using nitrogen, ammonia, or any similar material as the second reactant in the first atomic layer deposition process and plasma generated from nitrogen, ammonia, or any similar material as the second reactant in the second atomic layer deposition process.

1. A transistor comprising:
a semiconductor layer;
a gate insulating film on the semiconductor layer;
a gate electrode on the gate insulating film; and
a source electrode and a drain electrode disposed on the semiconductor layer with the gate electrode therebetween, wherein
a concentration of an impurity contained in the gate insulating film is on a downward gradient starting at a surface of the gate insulating film on a semiconductor layer side and ending at a surface of the gate insulating film on a gate electrode side.

2. The transistor according to claim 1, wherein the impurity includes either or both of a hydrogen atom and a carbon atom.

3. The transistor according to claim 1, wherein:
the gate insulating film has
a first gate insulating film formed through a first atomic layer deposition process using a first reactant and a second reactant, and
a second gate insulating film formed on the first gate insulating film through a second atomic layer deposition process using a first reactant and a second reactant;
the second reactant used in the second atomic layer deposition process is more reactive than the second reactant used in the first atomic layer deposition process; and
the second gate insulating film contains an impurity at a lower concentration than the first gate insulating film does.

4. The transistor according to claim 1, wherein the gate insulating film is made of an oxide material.

5. The transistor according to claim 4, wherein the oxide material is aluminum oxide.

6. The transistor according to claim 3, wherein:
the first reactant is trimethylaluminum;
the second reactant used in the first atomic layer deposition process is either ozone or vapor; and
the second reactant used in the second atomic layer deposition process is oxygen plasma.

7. The transistor according to claim 1, wherein the semiconductor layer includes an aluminum gallium nitride layer in contact with the gate insulating film and a gallium nitride layer in contact with the aluminum gallium nitride layer.

8. A method for producing a transistor, the method comprising:
providing a semiconductor layer;
forming a first gate insulating film on the semiconductor layer through a first atomic layer deposition process using a first reactant and a second reactant;
forming a second gate insulating film on the first gate insulating film through a second atomic layer deposition process using a first reactant and a second reactant;
forming a gate electrode on the second gate insulating film, and
forming a source electrode and a drain electrode on the semiconductor layer with the gate electrode therebetween, wherein:
the second reactant used in the second atomic layer deposition process is more reactive than the second reactant used in the first atomic layer deposition process; and
the second gate insulating film contains an impurity at a lower concentration than an impurity of the first gate insulating film.

9. The method for producing a transistor according to claim 8, wherein:
the first reactant is trimethylaluminum;
the second reactant used in the first atomic layer deposition process is either ozone or vapor; and
the second reactant used in the second atomic layer deposition process is oxygen plasma.

10. The method for producing a transistor according to claim 8, wherein:
the impurity includes either or both of a hydrogen atom and a carbon atom; and
the first gate insulating film and the second gate insulating film are made of aluminum oxide.
